(19) United States
(12) Patent Application Publication
(10) Pub. No.: US 2022/0274224 A1
(43) Pub. Date: Sep. 1, 2022

(54) GRINDING METHOD FOR WORKPIECE

(71) Applicant: DISCO CORPORATION, Tokyo (JP)

(72) Inventor: Yoshikazu SUZUKI, Tokyo (JP)

(21) Appl. No.: 17/650,899

(22) Filed: Feb. 14, 2022

(30) Foreign Application Priority Data
Mar. 1, 2021 (JP) 2021-031795

(51) Int. Cl. B24B 7/22; H01L 21/304; H01L 21/683

(52) U.S. Cl. CPC B24B 7/228; H01L 21/304; H01L 21/6836; H01L 2221/68327; H01L 2221/6834

(57) ABSTRACT

There is provided a grinding method for a workpiece, the method including a first grinding step of grinding the workpiece from a side of a back surface to form, in the workpiece, a disc-shaped first thin portion and an annular first thick portion which surrounds the first thin portion, a second grinding step of grinding the first thin portion from the side of the back surface to form a disc-shaped second thin portion, which is smaller in diameter and thickness than the first thin portion, and an annular second thick portion which surrounds the second thin portion, and a third grinding step of grinding the second thick portion and the second thin portion from the side of the back surface with use of finer grinding stones, thereby forming a disc-shaped third thin portion greater in diameter and smaller in thickness than the second thin portion.

### BACKGROUND OF THE INVENTION

### Field of the Invention

The present invention relates to a grinding method for a workpiece, especially a tabular workpiece such as a wafer.

### Description of the Related Art

To realize small size and lightweight device chips, there are increasing occasions to thinly process a wafer that includes devices such as integrated circuits arranged on a side of a front surface thereof. A wafer can be ground thin, for example, by holding it on a side of a front surface thereof on a chuck table, relatively rotating a grinding wheel, on which abrasive stones containing abrasive grains (grinding stones) are fixed, and the chuck table, and pressing the abrasive stones against a back surface of the wafer while supplying a liquid such as pure water.

If the wafer is thinned in its entirety in the above-mentioned manner, however, the wafer is significantly lowered in rigidity, thereby making it difficult to handle the wafer in subsequent steps. Accordingly, a technique has been proposed to maintain the rigidity of the wafer at a sufficiently high level after its grinding by grinding the wafer at a region on a center side (inner side) where devices are arranged, and leaving a region on an outer peripheral side (outer side) as it is without grinding the same (see, for example, JP 2009-176896A).

According to this technique, using a grinding wheel with grinding stones, which contain abrasive grains of a somewhat large size, fixed thereon, a wafer is first ground coarsely at a region on a side of a center thereof to form, in the wafer, a disc-shaped thin portion and an annular thick portion which surrounds the thin portion. The use of a grinding wheel with grinding stones, which contain such larger abrasive grains, fixed thereon as described above enables to reduce the time required for grinding the wafer compared with use of a grinding wheel with grinding stones, which contain relatively small abrasive grains, fixed thereon.

If a wafer is ground using a grinding wheel with grinding stones, which contain such larger abrasive grains, fixed thereon, however, a damaged layer with chips, scratches, fractures, and the like (hereinafter collectively called “damage”) and strain contained therein occur on a side of a ground surface, so that the resulting thin portion tends to have insufficient mechanical strength (flexural strength). After the wafer is coarsely ground, the resulting thin portion is hence further ground using a grinding wheel with grinding stones, which contain relatively small abrasive grains, fixed thereon, whereby the damaged layer is removed.

### SUMMARY OF THE INVENTION

It is to be understood that, if the grinding wheel comes to contact with a side surface or the like of the thick portion when the thin portion is ground to remove the damaged layer, the thick portion may be chipped. When the damaged layer is removed, the thin portion is therefore ground at only a region on a side of a center thereof to prevent the grinding wheel from coming into contact with the thick portion. In this manner, however, the damaged layer remains in a region on a side of an outer periphery of the thin portion (a region near a boundary with the thick portion). As a result, cracks then propagate from the remaining damaged layer toward a front surface of the wafer during subsequent transfer and the like, so that the devices are susceptible to damage.

The damage of the devices due to the propagation of the cracks from the damaged layer can be avoided if the thin portion is formed thick to leave a sufficiently large distance from the devices on the side of the front surface to the damaged layer. In this case, however, a large portion of the wafer has to be removed using a grinding wheel with grinding stones, which contain relatively small abrasive grains and has a small removable volume per unit time, fixed thereon, to thin the thin portion to a final thickness. In other words, the time required until completion of the grinding becomes significantly longer.

The present invention therefore has as an object thereof the provision of a grinding method for a tabular workpiece with devices arranged on a side of a front surface thereof, which, when the tabular workpiece is ground from a side of a back surface thereof, can suppress low the probability of damage of the devices, without a significant increase in the time until completion of the grinding.

In accordance with one aspect of the present invention, there is provided a grinding method for grinding a tabular workpiece, which includes a plurality of devices arranged on a side of a front surface thereof, from a side of a back surface opposite to the front surface with use of a grinding wheel mounted on a rotating spindle. The grinding method includes a bonding step of bonding a protective member to the front surface of the workpiece, a holding step of holding the workpiece on a first holding surface of a first chuck table via the protective member, a first grinding step of, with the workpiece held on the first holding surface of the first chuck table via the protective member, relatively moving a first grinding wheel, which includes first grinding stones containing abrasive grains, and the first chuck table in a direction intersecting the first holding surface, and grinding the workpiece from the side of the back surface, thereby forming, in the workpiece, a disc-shaped first thin portion and an annular first thick portion surrounding the first thin portion, a second grinding step of, after the first grinding step, relatively moving the first grinding wheel and the first chuck table in a direction intersecting the first holding surface, and grinding the first thin portion from the side of the back surface, thereby forming, in the first thin portion, a disc-shaped second thin portion smaller in diameter and thickness than the first thin portion and an annular second thick portion surrounding the second thin portion, and a third grinding step of, after the second grinding step, with the workpiece held on a second holding surface of a second chuck table via the protective member, relatively moving a second grinding wheel, which includes second grinding stones containing abrasive grains that are small compared with those of the first grinding stones, and the second chuck table in a direction intersecting the second holding surface, and grinding the second thick portion and the second thin portion from the side of the back surface, thereby forming a disc-shaped third thin portion greater in diameter and smaller in thickness than the second thin portion.

Preferably, the first chuck table may be used as the second chuck table. Also preferably, in the third grinding step, the second grinding wheel and the second chuck table may be relatively moved at a higher speed when only the second thick portion is ground than when a region including the second thin portion is ground.

Also preferably, in the first grinding step, the first thin portion may be formed to a thickness sufficient to prevent cracks, which propagate from a first damaged layer occurring in the workpiece in the first grinding step and containing damage or strain, from reaching one or more of the devices, and, in the second grinding step, the second thin portion may be formed to a thickness sufficient to prevent a second damaged layer, which occurs in the workpiece in the second grinding step and contains damage or strain, from reaching a region that is to become the third thin portion.

In the grinding method according to the one aspect of the present invention, after the first grinding step in which the workpiece is ground using the first grinding wheel including the first grinding stones with the relatively large abrasive grains contained therein to form, in the workpiece, the disc-shaped first thin portion and the annular first thick portion which surrounds the first thin portion, and the second grinding step in which the first thin portion is ground using the same first grinding wheel to form, in the first thin portion, the disc-shaped second thin portion, which is smaller in diameter and thickness than the first thin portion, and the annular second thick portion which surrounds the second thin portion, the third grinding step is performed to grind the second thick portion and the second thin portion with use of the second grinding wheel which includes the second grinding stones containing the relatively small abrasive grains, so that the disc-shaped third thin portion greater in diameter and smaller in thickness than the second thin portion is formed.

Compared with a case in which the third grinding step is performed without performing the second grinding step after the first grinding step, the amount (volume) of the portions to be removed through the third grinding step is thus reduced by the amount of the portion removed in the second grinding step. In other words, the time required for the third grinding step can be reduced in exchange for the addition of the second step that is completed in a short time with use of the first grinding wheel having a large removable volume per unit time. Therefore, the time required until completion of the grinding can be reduced compared with the case in which the third grinding step is performed without performing the second grinding step after the first grinding step.

It is therefore possible to avoid a substantial increase in the time until the completion of the grinding although the first thin portion is formed thick to leave a sufficient distance from the devices to the damaged layer for preventing damage of the devices due to cracks that propagate from the damaged layer occurring in the first grinding step and containing damage or strain. As appreciated from the foregoing, the grinding method according to the one aspect of the present invention can suppress low the probability of damage of devices, without a substantial increase in the time until the completion of the grinding.

The above and other objects, features and advantages of the present invention and the manner of realizing them will become more apparent, and the invention itself will best be understood from a study of the following description and appended claims with reference to the attached drawings showing a preferred embodiment of the invention.

### BRIEF DESCRIPTION OF THE DRAWINGS

FIG. 1 is a perspective view schematically depicting how a protective member is bonded to a tabular workpiece in a bonding step of a grinding method according to an embodiment of the present invention for a workpiece;

FIG. 2 is a cross-sectional view schematically depicting how the workpiece is held on a chuck table via the protective member in a holding step of the grinding method;

FIG. 3 is a cross-sectional view schematically depicting how the workpiece is ground by a first grinding wheel in a first grinding step;

FIG. 4 is a fragmentary cross-sectional view schematically depicting a portion of the workpiece after the workpiece has been ground by the first grinding wheel in the first grinding step;

FIG. 5 is a cross-sectional view schematically depicting how the chuck table and the first grinding wheel are relatively moved in a direction along an upper surface of the chuck table in a second grinding step after the first grinding step;

FIG. 6 is a cross-sectional view schematically depicting how a first thin portion of the workpiece is ground by the first grinding wheel in the second grinding step;

FIG. 7 is a fragmentary cross-sectional view schematically depicting a portion of the workpiece after the first thin portion has been ground by the first grinding wheel in the second grinding step;

FIG. 8 is a cross-sectional view schematically depicting how a second thick portion and a second thin portion of the workpiece are ground by a second grinding wheel in a third grinding step after the second grinding step; and

FIG. 9 is a fragmentary cross-sectional view schematically depicting a portion of the workpiece after the second thick portion and the second thin portion have been ground by the second grinding wheel in the third grinding step.

### DETAILED DESCRIPTION OF THE PREFERRED EMBODIMENT

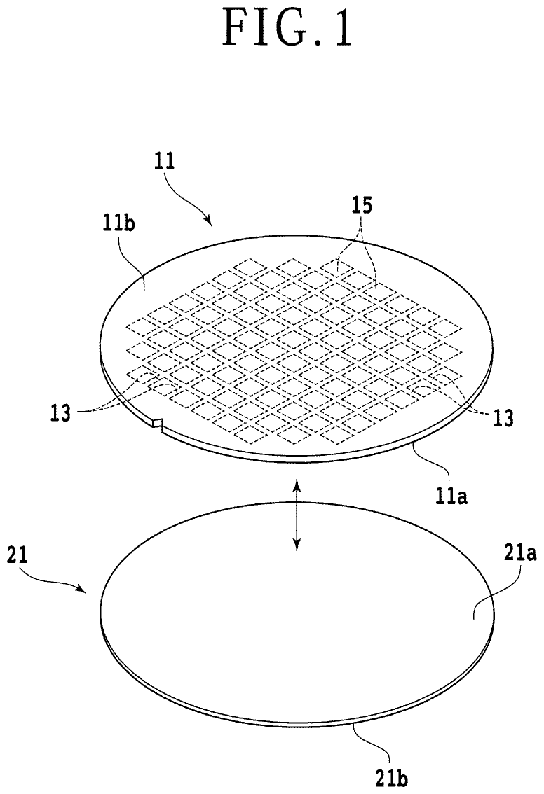

With reference to the attached drawings, a description will be made about a grinding method according to an embodiment of the present invention for a workpiece. In the grinding method of this embodiment, a protective member is first bonded to a tabular workpiece which is a grinding object (bonding step). FIG. 1 is a perspective view schematically depicting how the protective member 21 is bonded to the tabular workpiece 11 in the bonding step of the grinding method of this embodiment.

The workpiece 11 is typically a disc-shaped wafer made of a semiconductor such as silicon (Si). The workpiece 11 is divided on a side of a front surface 11a thereof into a plurality of small regions by a plurality of intersecting scribe lines (streets) 13, and devices 15 such as integrated circuits (ICs) are formed in the respective small regions. In this embodiment, the workpiece 11 is thinned at a portion thereof which corresponds to a region (device region) where the devices 15 are formed, by grinding the portion from a side of a back surface 11b opposite to the front surface 11a.

It is to be understood that the disc-shaped wafer made of the semiconductor such as silicon is used as the workpiece 11, although no limitations are imposed on the material, shape, structure, size, and the like of the workpiece 11 in this embodiment. For example, a substrate made of a material such as another semiconductor, ceramics, resin, or metal can also be used as the workpiece 11. Similarly, no limitations are imposed on the type, number, shape, structure, size, arrangement, and the like of the devices 15.

The protective member 21 to be bonded to the workpiece 11 is typically a circular tape (film), a resin substrate, or a wafer of a material of the same or a different kind as that of the workpiece 11, which has a diameter substantially equal to the workpiece 11. On a side of a front surface 21a of the protective member 21, an adhesive layer that exhibits an adhesive force to the workpiece 11 is arranged.

The protective member 21 can therefore be bonded to the workpiece 11 by bringing the protective member 21 into close contact, on the side of the front surface 21a, with the workpiece 11. In this embodiment, the protective member 21 is brought into close contact, on the side of the front surface 21a, with the front surface 11a of the workpiece 11 as depicted in FIG. 1, whereby the protective member 21 is bonded to the front surface 11a of the workpiece 11 (bonding step). As a consequence, the devices 15 and the like can be protected by cushioning impact that is to be applied to the front surface 11a when the workpiece 11 is ground from the side of the back surface 11b.

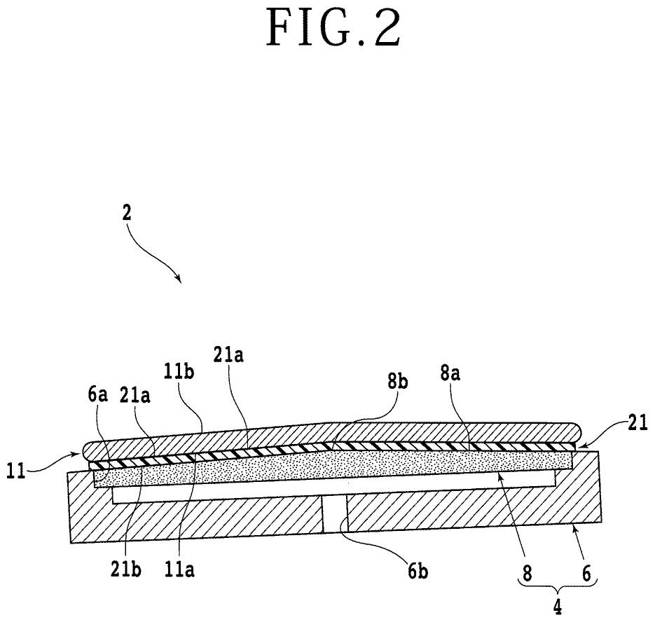

After the protective member 21 has been bonded to the front surface 11a of the workpiece 11, the workpiece 11 is held on a holding surface of a chuck table via the protective member 21 (holding step). Therefore, the protective member 21 bonded to the workpiece 11 is held on a side of a back surface 21b thereof on the chuck table. FIG. 2 is a cross-sectional view schematically depicting how the workpiece 11 is held on a chuck table 4 via the protective member 21. It is to be understood that, in each of subsequent steps, a grinding machine 2 depicted in FIG. 2, etc., will be used.

The grinding machine 2 includes the chuck table (first chuck table, second chuck table) 4 configured to enable holding the workpiece 11. The chuck table 4 includes a disc-shaped frame body 6 formed using, for example, metal represented by stainless steel. On a side of an upper surface of the frame body 6, a recessed portion 6a including a circular opening formed in an upper end thereof is formed. In the recessed portion 6a, a disc-shaped porous holding plate 8 formed using ceramics or the like is fixed.

The holding plate 8 is configured at an upper surface 8a thereof in a shape, for example, corresponding to a side surface of a flattened circular cone, and functions as the holding surface for holding the protective member 21. In this embodiment, the back surface 21b of the protective member 21 is brought into contact with the upper surface (first holding surface, second holding surface) 8a. The holding plate 8 is connected on a side of a lower surface thereof to a suction source (not depicted) such as an ejector via a flow passage 6b arranged inside the frame body 6, a valve (not depicted), and the like.

By bringing the back surface 21b of the protective member 21 into contact with the upper surface 8a of the holding plate 8 and opening the valve to apply a negative pressure of the suction source, the back surface 21b of the protective member 21 is therefore sucked by the chuck table 4. Therefore, the workpiece 11 is held by the chuck table 4 via the protective member 21 bonded to the workpiece 11.

As depicted in FIG. 2, the workpiece 11 is hence upwardly exposed on the side of the back surface 11b. It is to be understood that, although the shape of the upper surface 8a of the holding plate 8 is exaggerated in FIG. 2, etc., the difference in height (height difference) between an apex 8b of the upper surface 8a, the apex 8b corresponding to the apex of the flattened circular cone, and an outer peripheral edge of the upper surface 8a is actually 10 μm to 30 μm or so.

To a lower part of the frame body 6, a rotary drive source (not depicted) such as a motor is connected. By a force generated by this rotary drive source, the chuck table 4 is rotated about an axis along a vertical direction or an axis slightly tilted with respect to the vertical direction such that the apex 8b is located at a center of rotation. Further, the frame body 6 is supported by a chuck table moving mechanism (not depicted), and therefore the chuck table 4 is moved in a horizontal direction by a force generated by the chuck table moving mechanism.

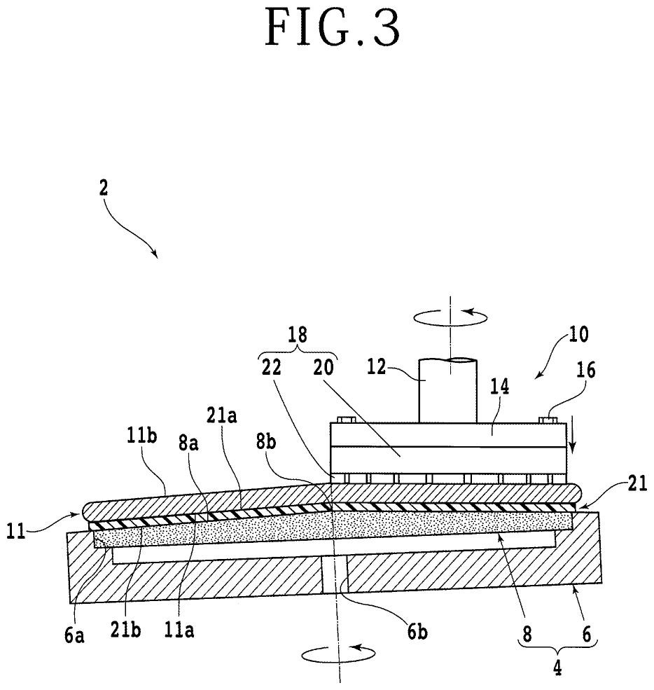

After the workpiece 11 has been held on the chuck table 4 via the protective member 21, the workpiece 11 is coarsely ground at the region thereof which corresponds to the region (device region) where the devices 15 are formed, from the side of the back surface 11b (first grinding step). FIG. 3 is a cross-sectional view schematically depicting how the workpiece 11 is coarsely ground in the first grinding step. It is to be understood that, in FIG. 3, some elements are depicted from a side profile for the sake of convenience of description.

As depicted in FIG. 3, etc., a first grinding unit (coarse grinding unit) 10 is disposed above the chuck table 4 of the grinding machine 2. The first grinding unit 10 includes, for example, a cylindrical spindle housing (not depicted). In an internal space of the spindle housing, a columnar spindle 12 is accommodated.

On a lower end portion of the spindle 12, a disc-shaped mount 14 is arranged. The mount 14 has, for example, a diameter smaller than the workpiece 11 and the protective member 21. In an outer peripheral portion of the mount 14, a plurality of holes (not depicted) extending through the mount 14 in a thickness direction is formed, and bolts 16 or the like are inserted in the respective holes. On a lower surface of the mount 14, a disc-shaped first grinding wheel (coarse grinding wheel) 18 of a diameter substantially equal to that of the mount 14 is fixed by the bolts 16 or the like.

The first grinding wheel 18 includes a disc-shaped wheel base 20 formed with metal such as stainless steel or aluminum. On a lower surface of the wheel base 20, a plurality of first grinding stones (coarse grinding stones) 22 is fixed along the direction of a periphery of the wheel base 20. The first grinding stones 22 have, for example, a structure in which somewhat large abrasive grains of diamond or the like are dispersed in a binder made of resin or the like.

The use of the first grinding wheel 18 with the first grinding stones 22 included therein leads to a large removable volume of the workpiece 11 per unit time, but is prone to form, on a side of the ground surface of the workpiece 11, a damaged layer which contains damage or strain. To a side of an upper end of the spindle 12, a rotary drive source (not depicted) such as a motor is connected. By a force generated by this rotary drive source, the first grinding wheel 18 is rotated about an axis along a vertical direction or an axis slightly tilted with respect to the vertical direction.

Beside or inside the first grinding wheel 18, a nozzle (not depicted) is arranged. The nozzle is configured to enable a supply of a grinding liquid (typically, pure water) to the first grinding stones 22, etc. The spindle housing is supported, for example, by a first grinding unit moving mechanism (not depicted), and the first grinding unit 10 is moved in the vertical direction by a force generated by the first grinding unit moving mechanism.

When the workpiece 11 is ground by the first grinding unit 10 (the first grinding wheel 18), the chuck table 4 is first moved to right below the first grinding unit 10. Described specifically, the chuck table 4 is moved in the horizontal direction by the chuck table moving mechanism such that the first grinding wheel 18 (all the first grinding stones 22) is disposed right above the region where the devices 15 are formed.

As depicted in FIG. 3, the chuck table 4 and the first grinding wheel 18 are then each rotated, and the first grinding unit 10 (the first grinding wheel 18) is lowered while the liquid is supplied from the nozzle. Therefore, the first grinding wheel 18 and the chuck table 4 are relatively moved in a direction intersecting the upper surface 8a, whereby the workpiece 11 is ground by the first grinding wheel 18. The lowering speed (grinding feed rate) of the first grinding unit 10 (the grinding feed rate) is adjusted to a range in which the first grinding stones 22 are pressed against the workpiece 11 under appropriate pressure.

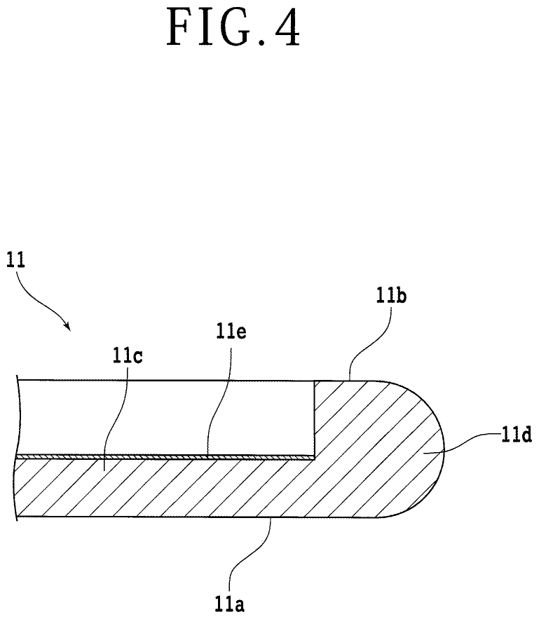

FIG. 4 is a fragmentary cross-sectional view schematically depicting a portion of the workpiece 11 after the workpiece 11 has been ground by the first grinding wheel 18. By grinding the workpiece 11 at the region thereof which corresponds to the region (device region) of the workpiece 11 where the devices 15 are formed, from the side of the back surface 11b as mentioned above, a disc-shaped first thin portion 11c, which corresponds to the region where the devices 15 are formed, and an annular first thick portion 11d surrounding the first thin portion 11c can be formed in the workpiece 11 as depicted in FIG. 4.

It is to be understood that a damaged layer (first damaged layer) 11e with damage or strain contained therein is formed in a portion (the ground surface) of the first thin portion 11c on the side of the back surface lib. Therefore, the first thin portion 11c may desirably be formed to a thickness sufficient to prevent cracks from reaching one or more of the devices 15 on the side of the front surface 11a even if the cracks propagate from the damaged layer 11e during subsequent transfer and the like.

No substantial limitations are imposed on specific grinding conditions. To realize efficient grinding of the workpiece 11, the rotational speed of the chuck table 4 may be set at 100 rpm to 600 rpm, typically 300 rpm, while the rotational speed of the first grinding wheel 18 may be set at 1,000 rpm to 7,000 rpm, typically 4,500 rpm. Further, the lowering speed of the first grinding unit 10 may be set at 0.8 μm/s to 10 μm/s, typically 6.0 μm/s.

After the disc-shaped first thin portion 11c and the annular first thick portion 11d which surrounds the first thin portion 11c have been formed by grinding the workpiece 11 from the side of the back surface 11b, the first thin portion 11c is coarsely ground by the same first grinding wheel 18 from the side of the back surface 11b (second grinding step). In this embodiment, the chuck table 4 and the first grinding wheel 18 are first relatively moved, whereby the first grinding wheel 18 is separated from an inner side surface of the first thick portion 11d.

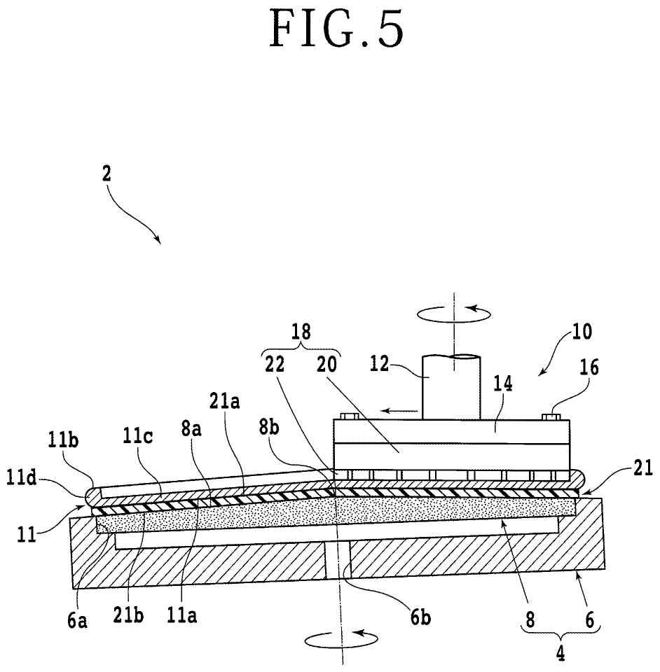

Described more specifically, the chuck table 4 and the first grinding wheel 18 are relatively moved in a direction along the upper surface 8a of the chuck table 4, whereby a clearance is formed between the first grinding wheel 18 and the first thick portion 11d. FIG. 5 is a cross-sectional view schematically depicting how the chuck table 4 and the first grinding wheel 18 are relatively moved in the direction along the upper surface 8a.

It is to be understood that, in FIG. 5, some elements are depicted from a side profile for the sake of convenience of description. It is also to be understood that, in FIG. 5, the chuck table 4 and the first grinding wheel 18 are relatively moved in the direction along the upper surface 8a while they are each kept rotating, but the chuck table 4 and the first grinding wheel 18 may be relatively moved in the direction along the upper surface 8a after they are stopped rotating. No substantial limitations are imposed on the moving speed and the moving distance. In this embodiment, however, the moving speed is set at 1.0 mm/s to 2.0 mm/s, and the moving distance is set at 3.0 mm to 6.0 mm.

After the clearance has been formed between the first grinding wheel 18 and the first thick portion 11d by relatively moving the chuck table 4 and the first grinding wheel 18, the first grinding unit 10 (the first grinding wheel 18) is lowered while the liquid is supplied from the nozzle. Therefore, the first grinding wheel 18 and the chuck tale 4 are relatively moved in the direction intersecting the upper surface 8a, whereby the first thin portion 11c is ground by the first grinding wheel 18.

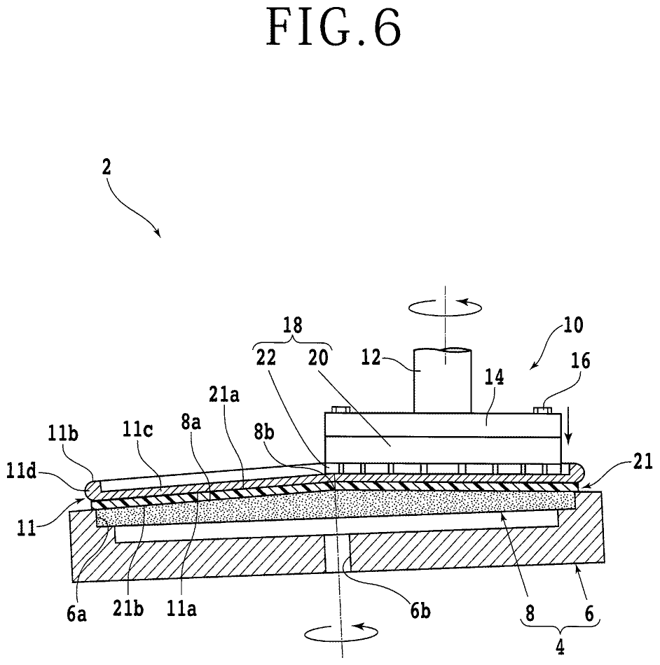

FIG. 6 is a cross-sectional view schematically depicting how the first thin portion 11c of the workpiece 11 is ground by the first grinding wheel 18. It is to be understood that, in FIG. 6, some elements are depicted from a side profile for the sake of convenience of description. The lowering speed (grinding feed rate) of the first grinding unit 10 is adjusted to a range in which the first grinding stones 22 are pressed against the first thin portion 11c under appropriate pressure.

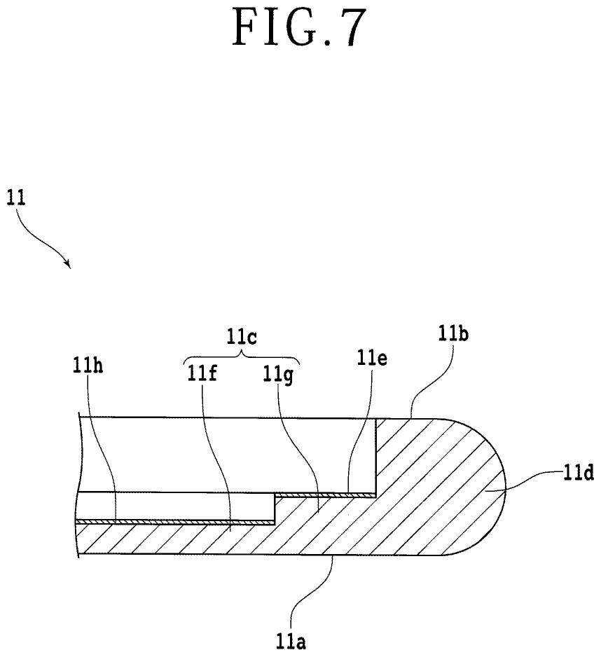

FIG. 7 is a fragmentary cross-sectional view schematically depicting a portion of the workpiece 11 after the first thin portion 11c has been ground by the first grinding wheel 18. By grinding the first thin portion 11c from the side of the back surface 11b as mentioned above, a disc-shaped second thin portion 11f and an annular second thick portion 11g surrounding the second thin portion 11f can be formed in the first thin portion 11c of the workpiece 11 as depicted in FIG. 7. After the second thin portion 11f and the second thick portion 11g have been formed, the first grinding unit 10 is lifted to end the grinding by the first grinding wheel 18.

It is to be understood that another damaged layer (second damaged layer) 11h with damage or strain contained therein is formed in a portion of the second thin portion 11f on the side of the back surface 11b (on a side of a ground surface). It is therefore desired to form the second thin portion 11f to a thickness sufficient to enable adequate removal of the damaged layer 11h by thinning the second thin portion 11f to a desired thickness through subsequent grinding.

No substantial limitations are imposed on specific grinding conditions. To realize efficient grinding of the first thin portion 11c of the workpiece 11, the rotational speed of the chuck table 4 may be set at 100 rpm to 600 rpm, typically 300 rpm, while the rotational speed of the first grinding wheel 18 may be set at 1,000 rpm to 7,000 rpm, typically 4,500 rpm.

Further, the lowering speed of the first grinding unit 10 may be set at 0.8 μm/s to 10 μm/s. Moreover, the lowering speed of the first grinding unit 10 may be changed as the grinding proceeds. Typically, the lowering speed is set at three levels, 6.0 μm/s, 3.0 μm/s, and 1.0 μm/s, sequentially as the grinding proceeds.

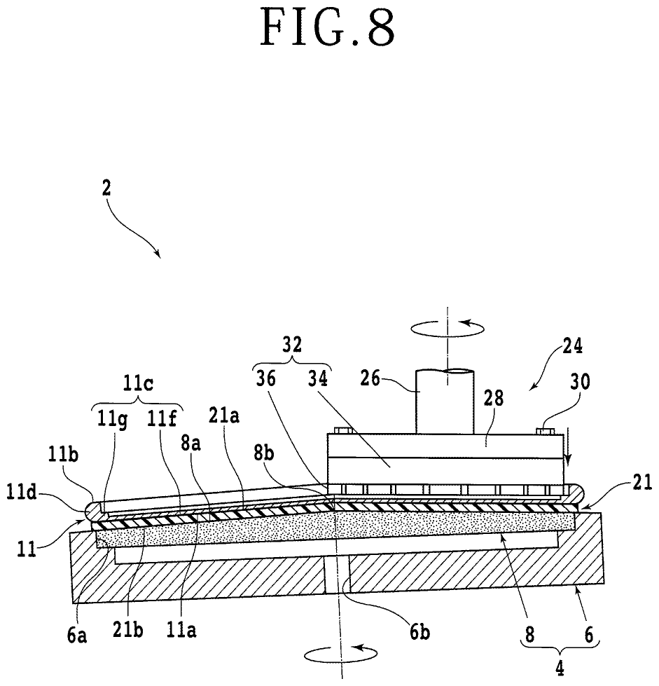

After the grinding by the first grinding wheel 18, the second thick portion 11g and the second thin portion 11f are ground with higher accuracy from the side of the back surface 11b (third grinding step). FIG. 8 is a cross-sectional view schematically depicting how the second thick portion 11g and the second thin portion 11f of the workpiece 11 are ground with higher accuracy. It is to be understood that, in FIG. 8, some elements are depicted from a side profile for the sake of convenience of description.

As depicted in FIG. 8, a second grinding unit (finish grinding unit) 24 which is different from the first grinding unit 10 is disposed above the chuck table 4 of the grinding machine 2. The second grinding unit 24 includes, for example, a cylindrical spindle housing (not depicted). In an internal space of the spindle housing, a columnar spindle 26 is accommodated.

On a lower end portion of the spindle 26, a disc-shaped mount 28 is arranged. The mount 28 has, for example, a diameter smaller than the workpiece 11 and the protective member 21. In an outer peripheral portion of the mount 28, a plurality of holes (not depicted) extending through the mount 28 in a thickness direction is formed, and bolts 30 or the like are inserted in the respective holes. On a lower surface of the mount 28, a disc-shaped second grinding wheel (finish grinding wheel) 32 of a diameter substantially equal to that of the mount 28 is fixed by the bolts 30 or the like.

The second grinding wheel 32 includes a disc-shaped wheel base 34 formed with metal such as stainless steel or aluminum. On a lower surface of the wheel base 34, a plurality of second grinding stones (finish grinding stones) 36 is fixed along the direction of a periphery of the wheel base 34. The second grinding stones 36 have, for example, a structure in which somewhat small abrasive grains of diamond or the like are dispersed in a binder made of resin or the like. Described specifically, the abrasive grains contained in the second grinding stones 36 have a small grain size (typically, average grain size) compared with the abrasive grains contained in the first grinding stones 22.

The use of the second grinding wheel 32 with the second grinding stones 36 included therein leads to a smaller removable volume of the workpiece 11 per unit time, but makes it hard to form a damaged layer, which contains damage or strain, on a side of the ground surface of the workpiece 11. To a side of an upper end of the spindle 26, a rotary drive source (not depicted) such as a motor is connected. By a force generated by this rotary drive source, the second grinding wheel 32 is rotated about an axis along a vertical direction or an axis slightly tilted with respect to the vertical direction.

Beside or inside the second grinding wheel 32, a nozzle (not depicted) is arranged. The nozzle is configured to enable a supply of a grinding liquid (typically, pure water) to the second grinding stones 36, etc. The spindle housing is supported, for example, by a second grinding unit moving mechanism (not depicted), and the second grinding unit 24 is moved in the vertical direction by a force generated by the second grinding unit moving mechanism.

When the second thick portion 11g and the second thin portion 11f are ground by the second grinding unit 24 (the second grinding wheel 32), the chuck table 4 is first moved to right below the second grinding unit 24. Described specifically, the chuck table 4 is moved in the horizontal direction by the chuck table moving mechanism such that the second grinding wheel 32 (all the second grinding stones 36) is disposed right above the second thick portion 11g and the second thin portion 11f.

As depicted in FIG. 8, the chuck table 4 and the second grinding wheel 32 are then each rotated, and the second grinding unit 24 (the second grinding wheel 32) is lowered while the liquid is supplied from the nozzle. In other words, the second grinding wheel 32 and the chuck table 4 are relatively moved in a direction intersecting the upper surface 8a. The lowering speed of the second grinding unit 24 (the grinding feed rate) is adjusted to a range in which the second grinding stones 36 are pressed against the workpiece 11 under appropriate pressure.

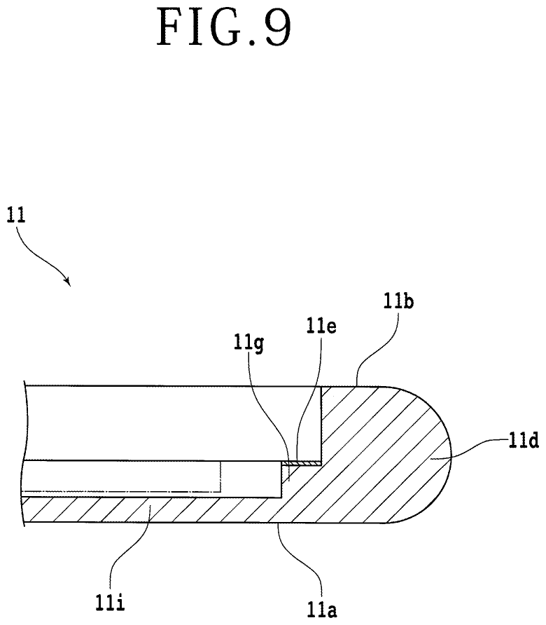

FIG. 9 is a fragmentary cross-sectional view schematically depicting a portion of the workpiece 11 after the second thick portion 11g and the second thin portion 11f have been ground by the second grinding wheel 32 in the third grinding step. By grinding the second thick portion 11g and the second thin portion 11f from the side of the back surface 11b as mentioned above, a disc-shaped third thin portion 11i greater in diameter and smaller in thickness than the second thin portion 11f can be formed in the workpiece 11 as depicted in FIG. 9. Further, the damaged layer 11h in the second thin portion 11f is removed through the grinding by the second grinding wheel 32.

No substantial limitations are imposed on specific grinding conditions. To realize efficient and highly-accurate grinding of the second thick portion 11g and the second thin portion 11f of the workpiece 11, the rotational speed of the chuck table 4 may be set at 100 rpm to 600 rpm, typically 300 rpm, while the rotational speed of the second grinding wheel 32 may be set at 1,000 rpm to 7,000 rpm, typically 4,000 rpm.

In the above-described grinding by the second grinding wheel 32, a region which includes the second thin portion 11f (and the second thick portion 11g) is ground after only the second thick portion 11g is ground. Here, it is to be understood that the area of a surface to be ground when only the second thick portion 11g is ground is small. In the stage of grinding the second thick portion 11g only, the lowering speed of the second grinding unit 24 can therefore be increased compared with that in the stage of grinding the region including the second thin portion 11f.

Hence, in this embodiment, the lowering speed of the second grinding unit 24 in the stage of grinding only the second thick portion 11g is set at 0.8 μm/s to 5.0 μm/s, and the lowering speed of the second grinding unit 24 in the stage of grinding the region including the second thin portion 11f is set at 0.1 μm/s to 0.8 μm/s.

In other words, the second grinding wheel 32 and the chuck table 4 are relatively moved at a higher speed when only the second thick portion 11g is ground than when the region including the second thin portion 11f is ground. Described typically, the relative moving speed between the second grinding wheel 32 and the chuck table 4 is set at 1.6 μm/s in the grinding of only the second thick portion 11g, and is sequentially set at two levels, 0.6 μm/s and 0.3 μm/s, as the grinding proceeds, in the grinding of the region including the second thin portion 11f.

As a consequence, it is possible to reduce the time to be required for the grinding and hence to increase the efficiency of the grinding, and further to sufficiently reduce the extent of damage or strain which is to occur at the third thin portion 11i. It is therefore possible to remove the damaged layer 11h which is close in distance to the devices 15 on the side of the front surface 11a and is prone to develop cracks that are to propagate to one or more of the devices 15 during subsequent transfer and the like, without substantially increasing the time to be required until completion of the grinding. Especially if the second thin portion 11f is formed with a thickness sufficient to prevent the damaged layer 11h from reaching the region that is to become the third thin portion 11i, the damaged layer 11h is sufficiently removed in association with the formation of the third thin portion 11i.

It is to be understood that the damaged layer 11e remains in a portion, which has not been ground by the second grinding wheel 32, on a side of an outer periphery of the second thick portion 11g (a portion in contact with the first thick portion 11d), but the distance from this remaining damaged layer 11e to the devices 15 on the side of the front surface 11a is great compared with the distance from the damaged layer 11h to the devices 15. Therefore, the probability of propagation of cracks from the remaining damaged layer 11e to one or more of the devices 15 on the side of the front surface 11a is low, so that the remaining damaged layer 11e does not pose a serious problem. Especially if the first thin portion 11c is formed with a thickness sufficient to prevent cracks, which propagate from the damaged layer 11e, from reaching one or more of the devices 15, the problem of such cracks is more appropriately eliminated.

A description will next be made about an example and a comparative example which were conducted to confirm advantageous effects of the grinding method according to this embodiment. In each of the example and the comparative example, the time required to form the third thin portion 11i to a thickness of 100 μm by grinding the first thin portion 11c, the thickness of which was 200 μm, was confirmed. In the example, the first thin portion 11c was ground using the first grinding wheel 18, whereby the second thin portion 11f and the second thick portion 11g were formed to a thickness of 130 μm and a thickness of 200 μm, respectively.

When the first thin portion 11c was ground, the lowering speed of the first grinding wheel 18 (the grinding feed rate) was set at three levels, 6.0 μm/s, 3.0 μm/s, and 1.0 μm/s, sequentially as the grinding proceeded. The lowered distances of the first grinding wheel 18 (in other words, the thicknesses removed by the grinding) at the respective speeds were 10 μm at the speed of 6.0 μm/s, 30 μm at the speed of 3.0 μm/s, and 30 μm at the speed of 1.0 μm/s.

Subsequently, the second thick portion 11g and the second thin portion 11f were ground using the second grinding wheel 32, whereby the third thin portion 11i was formed to a thickness of 100 μm. Described specifically, after only the second thick portion 11g was ground, the region with the second thin portion 11f (and the second thick portion 11g) included therein was ground. When only the second thick portion 11g was ground, the lowering speed of the second grinding wheel (the grinding feed rate) was set at 1.6 μm/s. The lowered distances of the second grinding wheel 32 was 70 μm.

When the region with the second thin portion 11f included therein was ground, on the other hand, the lowering speed of the second grinding wheel 32 was sequentially set at two levels, 0.6 μm/s and 0.3 μm/s, as the grinding proceeded. The lowered distances of the second grinding wheel 32 at the respective speeds were 20 μm at the speed of 0.6 μm/s, and 10 μm at the speed of 0.3 μm/s. In the example, a time of approximately 152 seconds was hence required until ending of the grinding.

In the comparative example, the first thin portion 11c the thickness of which was 200 μm was ground using the second grinding wheel 32, whereby the first thin portion 11c was thinned to a thickness of 100 μm (a thickness corresponding to the third thin portion 11i). When the first thin portion 11c was ground, the lowering speed of the second grinding wheel 32 was set at two levels, 0.6 μm/s and 0.3 μm/s, sequentially as the grinding proceeded. The lowered distances of the second grinding wheel 32 at the respective speeds were 90 μm at the speed of 0.6 μm/s, and 10 μm at the speed of 0.3 μm/s. In the comparative example, a time of approximately 183 seconds was hence required until ending of the grinding.

As appreciated from the foregoing, the time until ending of the grinding was shorter by 31 seconds in the example than in the comparative example. In the grinding method according to this embodiment, an additional time (1.5 to 6.0 seconds) was needed to relatively move the chuck table 4 and the first grinding wheel 18 in the direction along the upper surface 8a. Even with this additional time taken into account, the grinding method according to this embodiment is considered to be sufficiently effective.

As described above, in the grinding method according to this embodiment, the workpiece 11 is ground using the first grinding wheel 18 which includes the first grinding stones 22 containing relatively large abrasive grains, whereby the disc-shaped first thin portion 11c and the annular first thick portion 11d surrounding the first thin portion 11c are formed in the workpiece 11 (the first grinding step); the first thin portion 11c is ground using the same first grinding wheel 18, whereby the disc-shaped second thin portion 11f smaller in diameter and thickness than the first thin portion 11c and the annular second thick portion 11g surrounding the second thin portion 11f are formed in the first thin portion 11c (the second grinding step); and then, the second thick portion 11g and the second thin portion 11f are ground using the second grinding wheel 32 which includes the second grinding stones 36 containing relatively small abrasive grains, whereby the disc-shaped third thin portion 11i greater in diameter and smaller in thickness than the second thin portion 11f is formed (the third grinding step).

Compared with the conventional grinding method that form neither the second thin portion 11f nor the second thick portion 11g, the amount (volume) of the portion to be removed using the second grinding wheel 32 is reduced by the amount of the portion removed using the first grinding wheel 18 when the second thin portion 11f and the second thick portion 11g are formed. Therefore, the time of the grinding that uses the second grinding wheel 32 can be significantly reduced in exchange for a slight increase in the time of the grinding that uses the first grinding wheel 18 having a large removable volume per unit time. Taking the grinding method as a whole, the time required until completion of the grinding can be reduced accordingly.

It is therefore possible to avoid a substantial increase in the time until the completion of the grinding although the first thin portion 11c is formed thick to leave a sufficient distance from the devices 15 to the damaged layer 11e for preventing damage of the devices 15 due to cracks that propagate from the damaged layer (first damaged layer) 11e formed in the first thin portion 11c. As appreciated from the foregoing, the grinding method according to this embodiment can suppress low the probability of damage of the devices 15, without a substantial increase in the time until the completion of the grinding.

It is to be understood that the present invention can be practiced with various changes or modifications without being limited to the details of the above-mentioned embodiment. For example, in the above-mentioned embodiment, the workpiece 11 held on the chuck table 4 is ground by the second grinding wheel 32 after the workpiece 11 held on the chuck table 4 is ground by the first grinding wheel 18. Therefore, the first chuck table used when the workpiece 11 is ground by the first grinding wheel 18 is used, as it is, as the second chuck table used when the workpiece 11 is ground by the second grinding wheel 32.

As an alternative, after the workpiece 11 which is held on the chuck table 4 is ground by the first grinding wheel 18, the workpiece 11 is held on another chuck table different from the chuck table 4, and can then be ground by the second grinding wheel 32. Therefore, the first chuck table used when the workpiece 11 is ground by the first grinding wheel 18 and the second chuck table used when the workpiece 11 is ground by the second grinding wheel 32 may be different. Similarly, the grinding method according to the present invention may be performed selectively using a plurality of grinding machines.

In the above-mentioned embodiment, the first thin portion 11c is ground after the chuck table 4 and the first grinding wheel 18 are relatively moved in the direction along the upper surface 8a of the chuck table 4. However, the first thin portion 11c can also be ground in a different manner. For example, the first thin portion 11c may also be ground while the chuck table 4 and the first grinding wheel 18 are relatively being moved in the direction along the upper surface 8a of the chuck table 4. If this is the case, however, the inner side surface of the second thick portion 11g is tilted with respect to the front surface 11a or the like.

In the above-mentioned embodiment, the first thin portion 11c is ground after the chuck table 4 and the first grinding wheel 18 are relatively moved in the direction along the upper surface 8a of the chuck table 4. Therefore, the first thin portion 11c may remain unground at a central region thereof. If this is the case, the remaining portion of the first thin portion 11c may be removed together, for example, when the second thick portion 11g is ground by the second grinding wheel 32.

Moreover, the structures, methods, and the like according to the above-mentioned embodiment and the modifications can be practiced with changes or modifications as needed to such extent as not departing from the scope of the object of the present invention.

The present invention is not limited to the details of the above described preferred embodiment. The scope of the invention is defined by the appended claims and all changes and modifications as fall within the equivalence of the scope of the claims are therefore to be embraced by the invention.

What is claimed is:

1. A grinding method for grinding a tabular workpiece, which includes a plurality of devices arranged on a side of a front surface thereof, from a side of a back surface opposite to the front surface with use of a grinding wheel mounted on a rotating spindle, the method comprising:
a bonding step of bonding a protective member to the front surface of the workpiece;
a holding step of holding the workpiece on a first holding surface of a first chuck table via the protective member;
a first grinding step of, with the workpiece held on the first holding surface of the first chuck table via the protective member, relatively moving a first grinding wheel, which includes first grinding stones containing abrasive grains, and the first chuck table in a direction intersecting the first holding surface, and grinding the workpiece from the side of the back surface, thereby forming, in the workpiece, a disc-shaped first thin portion and an annular first thick portion surrounding the first thin portion;
a second grinding step of, after the first grinding step, relatively moving the first grinding wheel and the first chuck table in a direction intersecting the first holding surface, and grinding the first thin portion from the side of the back surface, thereby forming, in the first thin portion, a disc-shaped second thin portion smaller in diameter and thickness than the first thin portion and an annular second thick portion surrounding the second thin portion; and
a third grinding step of, after the second grinding step, with the workpiece held on a second holding surface of a second chuck table via the protective member, relatively moving a second grinding wheel, which includes second grinding stones containing abrasive grains that are small compared with those of the first grinding stones, and the second chuck table in a direction intersecting the second holding surface, and grinding the second thick portion and the second thin portion from the side of the back surface, thereby forming a disc-shaped third thin portion greater in diameter and smaller in thickness than the second thin portion.

2. The grinding method according to claim 1, wherein the first chuck table is used as the second chuck table.

3. The grinding method according to claim 1, wherein, in the third grinding step, the second grinding wheel and the second chuck table are relatively moved at a higher speed when only the second thick portion is ground than when a region including the second thin portion is ground.

4. The grinding method according to claim 1, wherein,
in the first grinding step, the first thin portion is formed to a thickness sufficient to prevent cracks, which propagate from a first damaged layer occurring in the workpiece in the first grinding step and containing damage or strain, from reaching one or more of the devices, and,
in the second grinding step, the second thin portion is formed to a thickness sufficient to prevent a second damaged layer, which occurs in the workpiece in the second grinding step and contains damage or strain, from reaching a region that is to become the third thin portion.
